(19) United States
(12) Patent Application Publication
(10) Pub. No.: US 2017/0117445 A1
(43) Pub. Date: Apr. 27, 2017

(54) LED PACKAGE COMPRISING RARE EARTH METAL OXIDE PARTICLES

(71) Applicant: HYOSUNG CORPORATION, Seoul (KR)

(72) Inventors: Sang Jun Lee, Ansan-si, Gyeonggi-do (KR); Jeong Gon Ryu, Hwaseong-si, Gyeonggi-do (KR); Da Hyun Go, Seoul (KR); Young Sic Kim, Seoul (KR); Seo Young Im, Seoul (KR); Kyung Ill Won, Bucheon-si, Gyeonggi-do (KR); Kwang Jin Park, Incheon (KR)

(21) Appl. No.: 15/317,908

(22) PCT Filed: Apr. 15, 2015
(86) PCT No.: PCT/KR2015/003799

§ 371 Date: Dec. 9, 2016

(30) Foreign Application Priority Data
Jun. 12, 2014 (KR) 10-2014-0071329
Jun. 12, 2014 (KR) 10-2014-0071595
Jun. 12, 2014 (KR) 10-2014-0071655

(51) Int. Cl. H01L 33/56; H01L 33/58

(52) U.S. Cl. CPC H01L 33/56; H01L 33/58

(57) ABSTRACT

The present invention relates to an LED package including rare-earth metal oxide particles and, more particularly, to an LED package including an LED chip selected from among a blue LED chip, a green LED chip and a red LED chip, and an LED encapsulant having a compound represented by Chemical Formula 1 below in a polymer resin.

Mₐ(OH)_{b}(CO₃)_{c}O_{d} [Chemical Formula 1]

In Chemical Formula 1, M is Sc, Y, La, Al, Lu, Ga, Zn, V, Zr, Ca, Sr, Ba, Sn, Mn, Bi or Ac, a is 1 or 2, b is 0 to 2, c is 0 to 3, and d is 0 to 3, wherein b, c, and d are not simultaneously zero, and b and c are either simultaneously zero or simultaneously not zero.

### TECHNICAL FIELD

The present invention relates to an LED (Light-Emitting Diode) package including rare-earth metal oxide particles and, more particularly, to a blue, green or red LED package including rare-earth metal oxide particles.

### BACKGROUND ART

An LED, which is a light-emitting element and is a type of semiconductor used to transmit and receive a signal by converting electricity into infrared rays or light using the characteristics of compound semiconductors, has been widely utilized as an illuminator or backlight for display devices due to advantages of high efficiency, a high-speed response, a long lifespan, small size and weight, and low electrical power consumption. The advanced application of LEDs in response to the global trend towards saving energy and the development of compound semiconductor technologies has led to the rapid industrialization of LEDs.

Typically, an LED package broadly includes an LED chip, an adhesive, an encapsulant, a phosphor, and heat-dissipation component. Among them, the LED encapsulant surrounds the LED chip, thus protecting the LED chip from external impacts and the environment.

However, since the LED light must pass through the LED encapsulant in order to be emitted from the LED package, the LED encapsulant must have high optical transparency, that is, high light transmittance, and is also required to have a high refractive index suitable for increasing light extraction efficiency.

An epoxy resin having a high refractive index and low cost has been widely used as the LED encapsulant. However, the epoxy resin has low heat resistance and may thus be deteriorated by the heat of high-power LEDs. Further, the epoxy resin suffers from decreased luminance due to yellowing caused by light near ultraviolet rays and blue light from white LEDs.

As an alternative thereto, silicone resin, having excellent light resistance in a low-wavelength range, is being used (the bonding energy of the siloxane bond (Si—O—Si) of the silicone resin is 106 kcal/mol, which is at least 20 kcal/mol higher than carbon-carbon (C—C) bonding energy, and accordingly, silicone resin is excellent in terms of heat resistance and light resistance). However, silicone resin has poor adhesion and light extraction efficiency due to its low refractive index.

Conventional techniques for encapsulants may be understood with reference to the following Patent Documents 1 and 2. Here, the entire contents of the following Patent Documents 1 and 2, as conventional techniques, are incorporated in the present specification.

Patent Document 1 discloses a curable liquid polysiloxane/TiO₂ composite to be used as an encapsulant for an LED which includes a polysiloxane prepolymer having a TiO₂ domain with an average domain size of less than 5 nm, which contains 20 to 60 mol % of TiO₂ (based on total solids), which has a refractive index of between 1.61 and 1.7, and which is in a liquid state at room temperature and atmospheric pressure.

Patent Document 2 discloses a composition for an encapsulant of an optoelectronic device, which includes an epoxy resin and polysilazane undergoing a curing reaction with the epoxy resin, an encapsulant formed using the composition, and an LED including the encapsulant.

### PRIOR ART DOCUMENTS

### Patent Literature

(Patent Document 1) Korean Patent Application Publication No. 10-2012-0129788 A (Nov. 28, 2012)

(Patent Document 2) Korean Patent Application Publication No. 10-2012-0117548 A (Oct. 24, 2012)

### DISCLOSURE

### Technical Problem

There are largely two methods for increasing the luminous efficiency of an LED.

The first method involves increasing the total quantity of light generated from a chip.

The second method includes emitting as much of the generated light as possible to the outside of the LED to thus increase the so-called light extraction efficiency.

As described above, a typical LED package includes an LED chip surrounded by an encapsulant, but only about 15% of the luminous energy generated in the chip is emitted in the form of light, and the remainder is absorbed by the encapsulant and the like.

Accordingly, in view of the luminous efficiency of LEDs, interest is being focused on improving light extraction efficiency so that the light generated in the light-emitting layer of the LED is effectively emitted to the outside without loss caused by total reflection in the LED chip.

Currently, various technologies are being studied to increase the light extraction efficiency so as to emit as much light as possible to the outside of the LED. However, there is still a need for further improvement.

Accordingly, the present invention is intended to provide an encapsulant composition that dramatically improves light extraction efficiency.

### Technical Solution

Therefore, the present invention has been made keeping in mind the above problems encountered in the prior art, and the present invention provides an LED package, comprising: any one of LED chip selected from among a blue LED chip, a green LED chip, and a red LED chip; and an LED encapsulant having a compound represented by Chemical Formula 1 below in a polymer resin.

Mₐ(OH)_{b}(CO₃)_{c}O_{d} [Chemical Formula 1]

Wherein 1, M is Sc, Y, La, Al, Lu, Ga, Zn, V, Zr, Ca, Sr, Ba, Sn, Mn, Bi or Ac, a is 1 or 2, b is 0 to 2, c is 0 to 3, and d is 0 to 3. However, b, c, and d are not simultaneously zero, and b and c are either simultaneously zero or simultaneously not zero.

Also, the present invention provides an LED package in which the compound represented by Chemical Formula may be Y(OH)CO₃.

Also, the present invention provides an LED package in which the compound represented by Chemical Formula 1 may be Y₂O₃.

Also, the present invention provides an LED package in which the compound represented by Chemical Formula 1 may be contained in an amount of 30 wt % or less relative to the total composition.

Also, the present invention provides an LED package in which the Y(OH)CO₃ may be contained in an amount of 1 to 20 wt % relative to the total composition.

Also, the present invention provides an LED package in which the Y₂O₃ may be contained in an amount of 20 wt % or less relative to the total composition.

Also, the present invention provides an LED package in which the compound represented by Chemical Formula 1 may be spherical particles having a sphericity of 0.5 to 1.

Also, the present invention provides an LED package in which the spherical particles may have a particle diameter ranging from 100 nm to 2 μm.

Also, the present invention provides an LED package in which the spherical particles may be monodispersed.

Also, the present invention provides an LED package in which the compound represented by Chemical Formula 1 may have a refractive index ranging from 1.6 to 2.3.

Also, the present invention provides an LED package in which the polymer resin is at least one selected from the group consisting of a silicone-based resin, a phenol-based resin, an acrylic resin, polystyrene, polyurethane, a benzoguanamine resin, and an epoxy-based resin.

Also, the present invention provides an LED package in which the LED package may further include phosphor particles.

Also, the present invention provides an LED package in which the blue LED chip may have an emission wavelength ranging from 400 to 500 nm, the green LED chip may have an emission wavelength ranging from 500 to 590 nm, and the red LED chip may have an emission wavelength ranging from 591 to 780 nm.

Also, the present invention provides an LED package in which the compound represented by Chemical Formula 1 may be uniformly distributed in the encapsulant.

### Advantageous Effects

According to the present invention, the LED package enables light, which is confined between the LED package chip and the encapsulant, to be emitted to the outside, thus exhibiting high luminous efficiency.

### DESCRIPTION OF DRAWINGS

FIG. 1 shows an LED package according to one embodiment of the present invention;

FIG. 2 shows an LED package according to another embodiment of the present invention; and

FIGS. 3 to 7 are calibration curves showing changes in luminance depending on the amount, particle size and sphericity of each of Y(OH)CO₃ particles and Y₂O₃ particles.

### MODE FOR INVENTION

Hereinafter, a detailed description will be given of the present invention.

The present invention addresses an LED package, comprising: any one of LED chip selected from among a blue LED chip, a green LED chip and a red LED chip, and an LED encapsulant having a compound represented by Chemical Formula 1 below in a polymer resin.

Mₐ(OH)_{b}(CO₃)_{c}O_{d} [Chemical Formula 1]

Wherein 1, M is Sc, Y, La, Al, Lu, Ga, Zn, V, Zr, Ca, Sr, Ba, Sn, Mn, Bi or Ac, a is 1 or 2, b is 0 to 2, c is 0 to 3, and d is 0 to 3.

Here, b, c, and d are not simultaneously zero, and b and c are either simultaneously zero or simultaneously not zero.

The compound of Chemical Formula 1 is preferably Y(OH)CO₃ or Y₂O₃, and more preferably Y(OH)CO₃ with respect to light extraction efficiency. This may be understood in greater detail through the Examples and Experimental Example, which will be described hereafter.

In the case where the compound of Chemical Formula 1 is contained in the polymer resin, the preferable amount thereof is within 30 wt % relative to the total composition. If very low amount of the compound is added, the increase in light extraction efficiency may become insignificant. On the other hand, if too much of the compound is added, the light extraction efficiency may be decreased instead. In other words, although the light extraction efficiency may vary depending on the wavelength of the light or the type of compound, the optimal amount range exists, which maximizes light extraction efficiency. Therefore, if the amount of the compound exceeds 30 wt %, regardless of the wavelength of light or the type of compound, the light extraction efficiency will be poor, which will be understood through a more detailed description thereof with reference to the following Examples and Experimental Example.

When the compound of Chemical Formula 1 is Y(OH)CO₃, it is preferable to add 1 to 20 wt % of the compound relative to the total composition. When it is Y₂O₃, the amount thereof may be 20 wt % or less based on the total amount of the composition. If the amount of the compound is out of range and is therefore low or high, it is difficult to obtain optimal luminance, which will be understood through a more detailed description thereof with reference to the following Examples and Experimental Example.

The compound of Chemical Formula 1 is preferably spherical particles having a sphericity of 0.5 to 1. Here, the sphericity of closer to 1 is more preferable. The sphericity is a value obtained by dividing the maximum diameter of a particle by the minimum diameter thereof, as defined in Equation 1 below. A value closer to 1 shows that the compound is closer to a complete sphere.

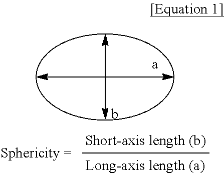

Such spherical particles preferably have a particle size ranging from 100 nm to 2 μm. Although the light extraction efficiency may vary depending on the type of compound of the spherical particles, if the particle size is less than 100 nm or exceeds 2 μm, the light extraction efficiency may decrease. Also, although the light extraction efficiency may vary depending on the type of particles, the optimal range of the light extraction efficiency depending on the particle size exists, and thus, particle size may be very important with regard to light extraction efficiency. This may be understood in greater detail through a more detailed description thereof with reference to the Examples and Experimental Example, which will be described later.

The spherical particles are preferably monodispersed, since when the particles are monodispersed, a predetermined refractive index may be assigned, thus improving light extraction efficiency.

It is preferable for the compound of Chemical Formula 1 to have a refractive index in the range of 1.6 to 2.3. If the refractive index is less than 1.6 or greater than 2.3, light extraction efficiency may not be increased. The reason is that the refractive index of a typical silicone encapsulant is about 1.5 and the refractive index of a GaN chip is about 2.4.

In a light-emitting element package chip, total reflection occurs at boundaries between the element and external air, or silicone which is an external encapsulant, or the like. According to Snell's law, the critical angle (ecrit) at which the light or waves passing through two isotropic media having different refractive indices can be emitted from the media to the outside is obtained using the following Equation.

$$θ crit = arcsin ( \frac{n 2}{n 1} )$$

The refractive index of GaN is about 2.5, which is largely different from that of air (nₐᵢᵣ=1) and silicone (n_{silicone}=1.5). Accordingly, the critical angle at which light generated in the light-emitting element package can be emitted to the outside is limited (θ_{GaN/air}=23° and θ_{GaN/Silicone}=37°, respectively). Therefore, light extraction efficiency is only about 15%.

The polymer resin is not particularly limited since the polymer resin widely used in prior art is used. For example, at least one selected from among a silicone-based resin, a phenol-based resin, an acrylic resin, polystyrene, polyurethane, a benzoguanamine resin, and an epoxy-based resin may be used. The silicone-based resin may be any one selected from among polysilane, polysiloxane, and a combination thereof. The phenol-based resin may be at least one phenol resin selected from among a bisphenol-type phenol resin, a resol-type phenol resin, and a resol-type naphthol resin. The epoxy-based resin may be at least one epoxy resin selected from among bisphenol F-type epoxy, bisphenol A-type epoxy, phenol novolak-type epoxy, and cresol novolak-type epoxy.

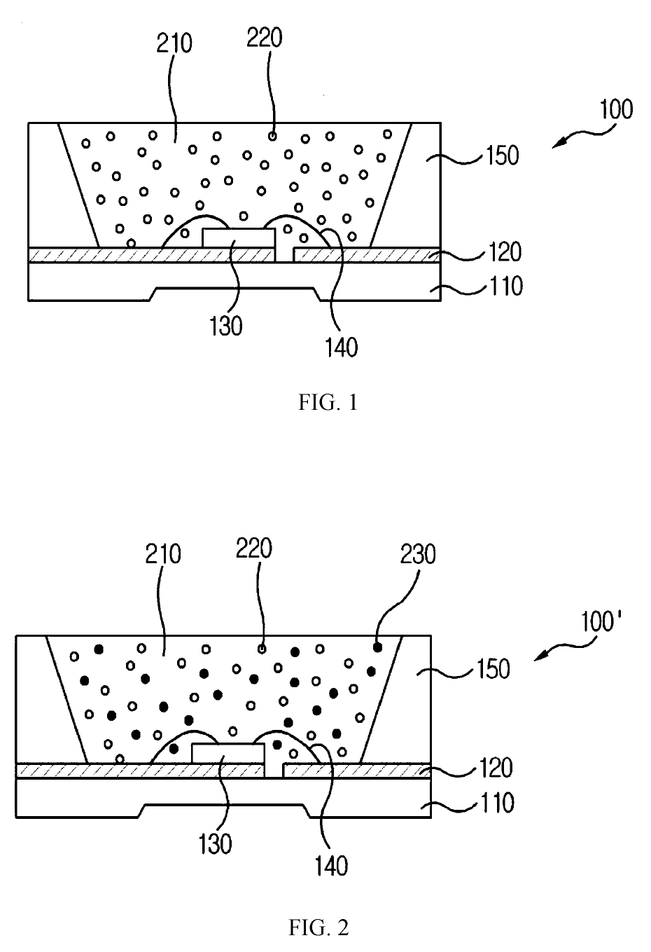

FIG. 1 shows the LED package according to an embodiment of the present invention. As shown in FIG. 1, the LED package 100 according to the present invention may be configured to include a substrate 110, a lead frame 120 formed on the substrate 110, an LED chip 130 formed on the lead frame 120 and emitting light, a bonding wire 140 for electrically connecting the LED chip 130 and the lead frame 120, a reflector 150 for reflecting the light emitted from the LED chip 130, and an encapsulant 200 charged in the reflector 150 so as to encapsulate the LED chip 130 and the bonding wire 140.

FIG. 2 shows the LED package according to another embodiment of the present invention. As shown in FIG. 2, the LED package 100′ according to the present invention may further include phosphor particles 230 so as to exhibit a desired color.

Hereafter, the present invention is described in more detail through the following examples, which are set forth to illustrate, but are not to be construed to limit the scope of the present invention.

### EXAMPLES

### Example 1

Y(OH)CO₃ particles were manufactured with 100 mL of distilled water as the standard. 4 g of yttrium nitrate hydrate and 40 g of urea were dissolved in 100 mL of distilled water and then mixed by sufficiently stirring for 30 min. After stirring, the pH of the resulting solution was adjusted to 5 to 6 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs, thus manufacturing particles having a size of 300 nm or less. The spherical particles obtained were monodispersed with a predetermined particle size.

The Y(OH)CO₃ particles were added to a silicone-based resin (a mixture comprising OE 6631 A and OE 6631 B at a ratio of 1:2) at a ratio of 98 wt % of silicone-based resin to 2 wt % of Y(OH)CO₃, after which the resulting mixture was placed in a homogenizer and homogenized, to prepare an encapsulant composition.

### Example 2

An encapsulant composition was prepared in the same manner as in Example 1, with the exception that the Y(OH)CO₃ particles were added to the silicone-based resin at a ratio of 98 wt % of silicone-based resin to 2 wt % of Y(OH)CO₃

### Example 3

An encapsulant composition was prepared in the same manner as in Example 1, with the exception that the Y(OH)CO₃ particles were added to the silicone-based resin at a ratio of 97 wt % of silicone-based resin to 3 wt % of Y(OH)CO₃

### Example 4

An encapsulant composition was prepared in the same manner as in Example 1, with the exception that the Y(OH)CO₃ particles were added to the silicone-based resin at a ratio of 93 wt % of silicone-based resin to 7 wt % of Y(OH)CO₃.

### Example 5

An encapsulant composition was prepared in the same manner as in Example 1, with the exception that the Y(OH)CO₃ particles were added to the silicone-based resin at a ratio of 90 wt % of silicone-based resin to 10 wt % of Y(OH)CO₃.

### Example 6

Y₂O₃ particles were obtained by manufacturing and then firing Y(OH)CO₃. 100 mL of distilled water was used as a standard for Y(OH)CO₃. Specifically, 4 g of yttrium nitrate hydrate and 40 g of urea were dissolved in 100 mL of distilled water and then mixed by sufficiently stirring for 30 min. After stirring, the pH of the resulting solution was adjusted to 5 to 6 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs. Then the dried Y(OH)CO₃ particles were fired at 900° C. for 3 hrs in an oxidizing atmosphere, to obtain Y₂O₃ particles having a size of 300 nm or less.

FIG. 2 shows a scanning electron microscope (SEM) image of the manufactured particles.

The Y₂O₃ particles were added to a silicone-based resin (a mixture comprising OE 6631 A and OE 6631 B at a ratio of 1:2) (99 wt % of the silicone-based resin and 1 wt % of the Y₂O₃), after which the resulting mixture was placed in a homogenizer and homogenized, to prepare an encapsulant composition.

### Example 7

An encapsulant composition was prepared in the same manner as in Example 6, with the exception that the Y₂O₃ particles were added to the silicone-based resin at a ratio of 98 wt % of silicone-based resin to 2 wt % of Y₂O₃.

### Example 8

An encapsulant composition was prepared in the same manner as in Example 6, with the exception that the Y₂O₃ particles were added to the silicone-based resin at a ratio of 97 wt % of silicone-based resin to 3 wt % of Y₂O₃.

### Example 9

An encapsulant composition was prepared in the same manner as in Example 6, with the exception that the Y₂O₃ particles were added to the silicone-based resin at a ratio of 93 wt % of silicone-based resin to 7 wt % of Y₂O₃.

### Example 10

An encapsulant composition was prepared in the same manner as in Example 6, with the exception that the Y₂O₃ particles were added to the silicone-based resin at a ratio of 90 wt % of silicone-based resin to 10 wt % of Y₂O₃.

### Example 11

100 mL of distilled water was used as a standard for Y(OH)CO₃ particles. 2 g of yttrium nitrate hydrate and 40 g of urea were dissolved in 100 mL of distilled water and then mixed by sufficiently stirring for 30 min. After stirring, the pH of the resulting solution was adjusted to 5.7 to 5.8 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs, thus manufacturing particles having a size of 100 nm or less.

The Y(OH)CO₃ particles were added to a silicone-based resin (a mixture comprising OE 6631 A and OE 6631 B at a ratio of 1:2) (97 wt % of the silicone-based resin and 3 wt % of the Y(OH)CO₃), and the resulting mixture was placed in a homogenizer and homogenized, to prepare an encapsulant composition.

### Example 12

100 mL of distilled water was used as a standard for Y(OH)CO₃ particles. 2 g of yttrium nitrate hydrate and 40 g of urea were dissolved in 100 mL of distilled water and then mixed by sufficiently stirring for 30 min. After stirring, the pH of the resulting solution was adjusted to 5.5 to 5.6 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs, thus manufacturing particles having a size of 500 nm or less.

The Y(OH)CO₃ particles were added to a silicone-based resin (a mixture comprising OE 6631 A and OE 6631 B at a ratio of 1:2) (97 wt % of the silicone-based resin and 3 wt % of the Y(OH)CO₃), and the resulting mixture was placed in a homogenizer and homogenized, to prepare an encapsulant composition.

### Example 13

100 mL of distilled water was used as a standard for Y(OH)CO₃ particles. 2 g of yttrium nitrate hydrate and 40 g of urea were dissolved in 100 mL of distilled water and then mixed by sufficiently stirring for 30 min. After stirring, the pH of the resulting solution was adjusted to 5.4 to 5.5 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs, thus manufacturing particles having a size of 1 μm or less.

The Y(OH)CO₃ particles were added to a silicone-based resin (a mixture comprising OE 6631 A and OE 6631 B at a ratio of 1:2) (97 wt % of the silicone-based resin and 3 wt % of the Y(OH)CO₃), and the resulting mixture was placed in a homogenizer and homogenized, to prepare an encapsulant composition.

### Example 14

100 mL of distilled water was used as a standard for Y(OH)CO₃ particles. 2 g of yttrium nitrate hydrate and 40 g of urea were dissolved in 100 mL of distilled water and then mixed by sufficiently stirring for 30 min. After stirring, the pH of the resulting solution was adjusted to 5.2 to 5.3 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs, thus manufacturing particles having a size of 2 μm or less.

The Y(OH)CO₃ particles were added to a silicone-based resin (a mixture comprising OE 6631 A and OE 6631 B at a ratio of 1:2) (97 wt % of the silicone-based resin and 3 wt % of the Y(OH)CO₃), and the resulting mixture was placed in a homogenizer and homogenized, to prepare an encapsulant composition.

### Example 15

Y₂O₃ particles were obtained by manufacturing and then firing Y(OH)CO₃. 100 mL of distilled water was used as a standard for Y(OH)CO₃. 2 g of yttrium nitrate hydrate and 40 g of urea were dissolved in 100 mL of distilled water and then mixed by sufficiently stirring for 30 min. After stirring, the pH of the resulting solution was adjusted to 5.7 to 5.8 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs. Then the dried Y(OH)CO₃ particles were fired at 900° C. for 3 hrs in an oxidizing atmosphere, to obtain Y₂O₃ particles having a size of 100 nm or less.

The Y₂O₃ particles were added to a silicone-based resin (a mixture comprising OE 6631 A and OE 6631 B at a ratio of 1:2) (97 wt % of the silicone-based resin and 3 wt % of the Y₂O₃), after which the resulting mixture was placed in a homogenizer and homogenized, to prepare an encapsulant composition.

### Example 16

Y₂O₃ particles were obtained by manufacturing and then firing Y(OH)CO₃. 100 mL of distilled water was used as a standard for Y(OH)CO₃. 2 g of yttrium nitrate hydrate and 40 g of urea were dissolved in 100 mL of distilled water and then mixed by sufficiently stirring for 30 min. After stirring, the pH of the resulting solution was adjusted to 5.5 to 5.6 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs. Then the dried Y(OH)CO₃ particles were fired at 900° C. for 3 hrs in an oxidizing atmosphere, to obtain Y₂O₃ particles having a size of 500 nm or less.

The Y₂O₃ particles were added to a silicone-based resin (a mixture comprising OE 6631 A and OE 6631 B at a ratio of 1:2) (97 wt % of the silicone-based resin and 3 wt % of the Y₂O₃), after which the resulting mixture was placed in a homogenizer and homogenized, to prepare an encapsulant composition.

### Example 17

Y₂O₃ particles were obtained by manufacturing and then firing Y(OH)CO₃. 100 mL of distilled water was used as a standard for Y(OH)CO₃. 2 g of yttrium nitrate hydrate and 40 g of urea were dissolved in 100 mL of distilled water and then mixed by sufficiently stirring for 30 min. After stirring, the pH of the resulting solution was adjusted to 5.4 to 5.5 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs. then the dried Y(OH)CO₃ particles were fired at 900° C. for 3 hrs in an oxidizing atmosphere, to obtain Y₂O₃ particles having a size of 1 μm or less. FIG. 6 shows an SEM image of the manufactured Y₂O₃ particles having a size of 1 μm or less.

The Y₂O₃ particles were added to a silicone-based resin (a mixture comprising OE 6631 A and OE 6631 B at a ratio of 1:2) (97 wt % of the silicone-based resin and 3 wt % of the Y₂O₃), after which the resulting mixture was placed in a homogenizer and homogenized, to prepare an encapsulant composition.

### Example 18

Y₂O₃ particles were obtained by manufacturing and then firing Y(OH)CO₃. 100 mL of distilled water was used as a standard for Y(OH)CO₃. 2 g of yttrium nitrate hydrate and 40 g of urea were dissolved in 100 mL of distilled water and then mixed by sufficiently stirring for 30 min. After stirring, the pH of the resulting solution was adjusted to 5.2 to 5.3 using nitric acid and ammonium hydroxide as a base. The mixed solution was heated to 90° C. and stirred for 1 hr, filtered, and washed three times with distilled water. The washed Y(OH)CO₃ particles were dried in an oven at 70° C. for 3 hrs. then the dried Y(OH)CO₃ particles were fired at 900° C. for 3 hrs in an oxidizing atmosphere, to obtain Y₂O₃ particles having a size of 2 μm or less.

The Y₂O₃ particles were added to a silicone-based resin (a mixture comprising OE 6631 A and OE 6631 B at a ratio of 1:2) (97 wt % of the silicone-based resin and 3 wt % of the Y₂O₃), after which the resulting mixture was placed in a homogenizer and homogenized, to prepare an encapsulant composition.

### Example 19

### Sphericity of Less Than 0.5

Y₂O₃ particles were obtained by manufacturing and then firing Y(OH)CO₃. 100 mL of distilled water was used as a standard for Y(OH)CO₃. 0.5 g of yttrium nitrate hydrate and 40 g of urea were dissolved in 100 mL of distilled water, then the pH of the resulting solution was adjusted to 5 to 6 using nitric acid and mixed by sufficiently stirring for 30 min. The mixed solution was heated to 60° C. and stirred for 30 min, and the pH thereof was adjusted to 8 to 9 using ammonium hydroxide and stirred for 1 hr. The resulting solution was filtered and then washed three times with distilled water. The washed Y(OH)CO₃ particles were dried in an oven at 70° C. for 3 hrs, fired at 900° C. for 6 hrs in an oxidizing atmosphere, and then milled, thereby reducing the particle size to 300 nm.

The particles were not spherical, and the sphericity thereof was measured to be less than 0.5.

The Y₂O₃ particles were added to a silicone-based resin (a mixture comprising OE 6631 A and OE 6631 B at a ratio of 1:2) (99 wt % of the silicone-based resin and 1 wt % of the Y₂O₃), after which the resulting mixture was placed in a homogenizer and homogenized, to prepare an encapsulant composition.

### Example 20

### Sphericity of Less Than 0.5

An encapsulant composition was prepared in the same manner as in Example 19, with the exception that the Y₂O₃ particles were added to the silicone-based resin at a ratio of 98 wt % of silicone-based resin to 2 wt % of Y₂O₃.

### Example 21

### Sphericity of Less Than 0.5

An encapsulant composition was prepared in the same manner as in Example 19, with the exception that the Y₂O₃ particles were added to the silicone-based resin at a ratio of 98 wt % of silicone-based resin to 3 wt % of Y₂O₃.

### Example 22

### Sphericity of Less Than 0.5

An encapsulant composition was prepared in the same manner as in Example 19, with the exception that the Y₂O₃ particles were added to the silicone-based resin at a ratio of 98 wt % of silicone-based resin to 7 wt % of Y₂O₃.

### Example 23

### Sphericity of Less Than 0.5

An encapsulant composition was prepared in the same manner as in Example 19, with the exception that the Y₂O₃ particles were added to the silicone-based resin at a ratio of 98 wt % of silicone-based resin to 10 wt % of Y₂O₃.

### Example 24

An encapsulant composition was prepared in the same manner as in Example 1, with the exception that the Y(OH)CO₃ particles were added to the silicone-based resin at a ratio of 90 wt % of silicone-based resin to 13 wt % of Y(OH)CO₃.

### Example 25

An encapsulant composition was prepared in the same manner as in Example 6, with the exception that the Y₂O₃ particles were added to the silicone-based resin at a ratio of 90 wt % of silicone-based resin to 13 wt % of Y₂O₃.

### Comparative Example

A 100 wt % encapsulant composition was prepared by mixing a silicone-based resin OE 6631 A and OE 6631 B at a ratio of 1:2.

### Experimental Example

### Luminance Measurement Experiment

The luminance increase was measured in the case where the encapsulant compositions of Examples 1 to 23 and Comparative Example were included in an LED package having a blue LED (a wavelength of 450 nm) chip, the case where the encapsulant compositions of Examples 1 to 25 and Comparative Example were included in an LED package having a green LED (a wavelength of 520 nm) chip, and the case where the encapsulant compositions of Examples 1 to 25 and Comparative Example were included in an LED package having a red LED (a wavelength of 620 nm) chip. The used LED package uses the chip connected on a lead frame through die bonding as a light-emitting source. The LED package is configured such that the LED and the lead frame are electrically connected through metal wire bonding and then molded with an encapsulant consisting of a silicone resin which is material for a transparent encapsulating material and inorganic nanoparticles dispersed therein. The luminance increase rate is the degree of increase in luminance on the basis of the Comparative Example 100, expressed as a percentage. Luminance was measured using a DARSA Pro 5200 PL system of Professional Scientific Instrument Company, Korea.

The measurement results in the case where the encapsulant compositions of Examples 1 to 23 and Comparative Example were included in an LED package having a blue LED (a wavelength of 450 nm) chip are shown in Tables 1 to 3 below.

TABLE 1

| | Compar- | | | | | | | | | | |
|---|---|---|---|---|---|---|---|---|---|---|---|
| | ative Ex. | Ex. 1 | Ex. 2 | Ex. 3 | Ex. 4 | Ex. 5 | Ex. 6 | Ex. 7 | Ex. 8 | Ex. 9 | Ex. 10 |
| Luminance | 100 | 99.7 | 102.9 | 105.9 | 110.1 | 109.6 | 107.6 | 107.1 | 102.6 | 87.6 | 77.1 |
| increase | | | | | | | | | | | |
| rate (%) | | | | | | | | | | | |

TABLE 2

| | Compar- | | | | | | | | |
|---|---|---|---|---|---|---|---|---|---|
| | ative Ex. | Ex. 11 | Ex. 12 | Ex. 13 | Ex. 14 | Ex. 15 | Ex. 16 | Ex. 17 | Ex. 18 |
| Luminance | 100 | 102.3 | 106.4 | 105.9 | 103.1 | 100.5 | 107.1 | 102.7 | 97.6 |
| increase | | | | | | | | | |
| rate (%) | | | | | | | | | |

TABLE 3

| | Compar- | | | | | |
|---|---|---|---|---|---|---|
| | ative Ex. | Ex. 19 | Ex. 20 | Ex. 21 | Ex. 22 | Ex. 23 |
| Luminance | 100 | 101.2 | 100.5 | 99.6 | 96.3 | 87.6 |
| increase | | | | | | |
| rate (%) | | | | | | |

The measurement results in the case where the encapsulant compositions of Examples 1 to 25 and Comparative Example were included in an LED package having a green LED (a wavelength of 520 nm) chip are shown in Tables 4 to 6 below.

TABLE 4

| | Compar- | | | | | | | | | | |
|---|---|---|---|---|---|---|---|---|---|---|---|
| | ative Ex. | Ex. 1 | Ex. 2 | Ex. 3 | Ex. 4 | Ex. 5 | Ex. 6 | Ex. 7 | Ex. 8 | Ex. 9 | Ex. 10 |
| Luminance | 100 | 102.3 | 102.6 | 104.7 | 108.6 | 113.2 | 104.7 | 103.5 | 104.1 | 100.4 | 94.6 |
| increase | | | | | | | | | | | |
| rate (%) | | | | | | | | | | | |

TABLE 5

| | Compar- | | | | | | | | |
|---|---|---|---|---|---|---|---|---|---|
| | ative Ex. | Ex. 11 | Ex. 12 | Ex. 13 | Ex. 14 | Ex. 15 | Ex. 16 | Ex. 17 | Ex. 18 |
| Luminance | 100 | 103.2 | 113.2 | 107.6 | 102.1 | 102.1 | 105.2 | 106.3 | 99.7 |
| increase | | | | | | | | | |
| rate (%) | | | | | | | | | |

TABLE 6

| | Compar- | | | | | | | |
|---|---|---|---|---|---|---|---|---|
| | ative Ex. | Ex. 19 | Ex. 20 | Ex. 21 | Ex. 22 | Ex. 23 | Ex. 24 | Ex. 25 |
| Luminance | 100 | 100.8 | 100.5 | 99.3 | 94.1 | 92.4 | 105.3 | 92.2 |
| increase | | | | | | | | |
| rate (%) | | | | | | | | |

The measurement results in the case where the encapsulant compositions of Examples 1 to 25 and Comparative Example were included in an LED package having a red LED (a wavelength of 620 nm) chip are shown in Tables 7 to 9 below.

TABLE 7

| | Compar- | | | | | | | | | | |
|---|---|---|---|---|---|---|---|---|---|---|---|
| | ative Ex. | Ex. 1 | Ex. 2 | Ex. 3 | Ex. 4 | Ex. 5 | Ex. 6 | Ex. 7 | Ex. 8 | Ex. 9 | Ex. 10 |
| Luminance | 100 | 100.7 | 100.9 | 102.8 | 106.3 | 108.4 | 101.6 | 104.6 | 103.6 | 102.7 | 98.5 |
| increase | | | | | | | | | | | |
| rate (%) | | | | | | | | | | | |

TABLE 8

| | Compar- | | | | | | | | |
|---|---|---|---|---|---|---|---|---|---|
| | ative Ex. | Ex. 11 | Ex. 12 | Ex. 13 | Ex. 14 | Ex. 15 | Ex. 16 | Ex. 17 | Ex. 18 |
| Luminance | 100 | 100.5 | 102.7 | 106.5 | 105.8 | 101.2 | 102.8 | 102.5 | 103.6 |
| increase | | | | | | | | | |
| rate (%) | | | | | | | | | |

TABLE 9

| | Compar- | | | | | | | |
|---|---|---|---|---|---|---|---|---|
| | ative Ex. | Ex. 19 | Ex. 20 | Ex. 21 | Ex. 22 | Ex. 23 | Ex. 24 | Ex. 25 |
| Luminance | 100 | 100.8 | 100.5 | 99.3 | 94.1 | 92.4 | 109.2 | 96.2 |
| increase | | | | | | | | |
| rate (%) | | | | | | | | |

As is apparent from Tables 1 to 9, when the rare-earth metal oxide inorganic particles were contained in the encapsulant composition, the luminance was found to be drastically increased. As such, compared to the Y(OH)CO₃ particles, the Y₂O₃ particles exhibited a high luminance increase when present in low amounts, but a low luminance increase when present in high amounts. The maximum luminance increase of the Y₂O₃ particles was also lower than that of the Y(OH)CO₃ particles.

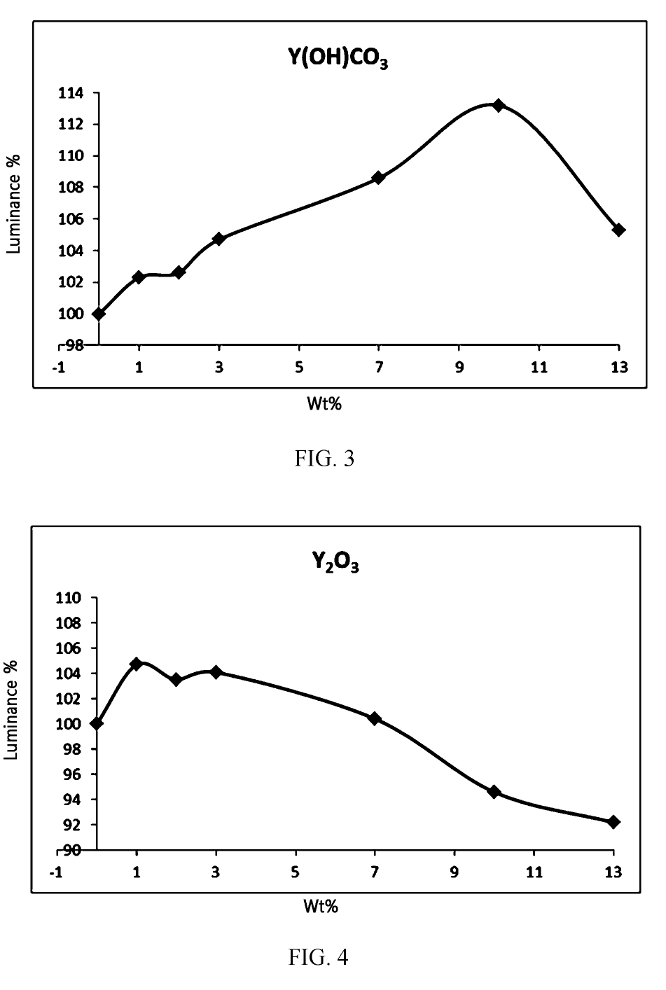

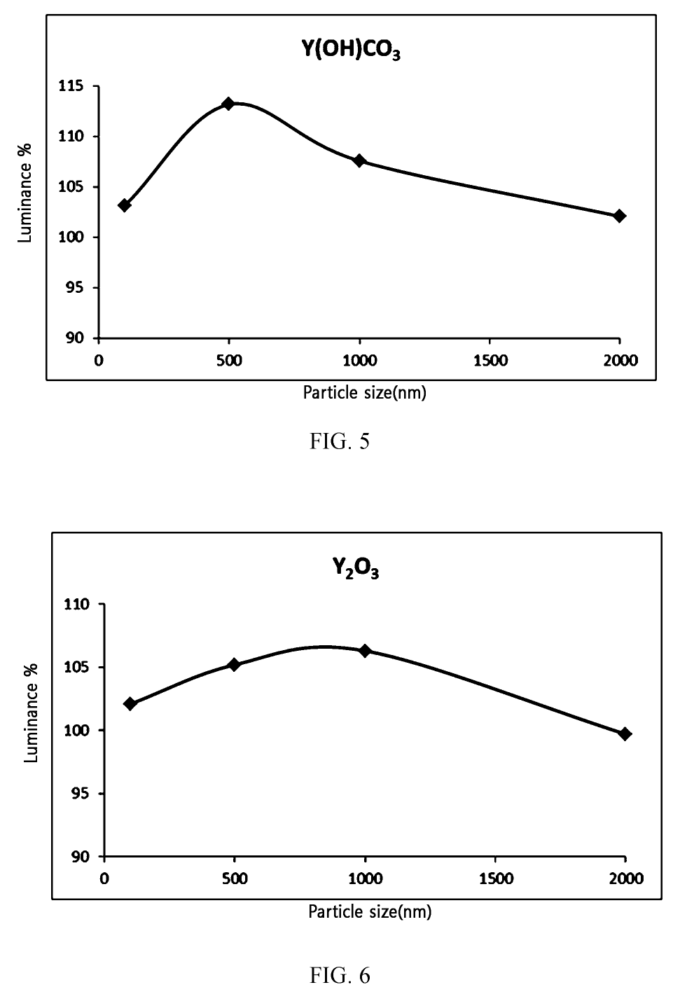

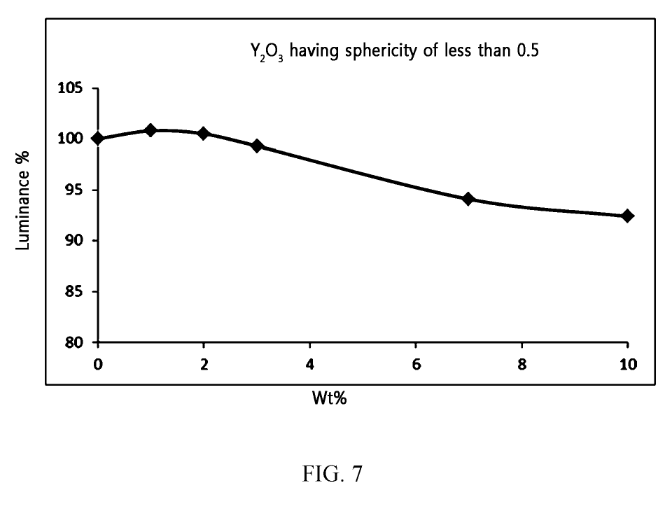

FIGS. 3 to 7 are calibration curves showing changes in luminance according to the amount, particle size and sphericity of each of Y(OH)CO₃ particles and Y₂O₃ particles. The ranges of the amount, particle size and sphericity of the particles, representing the maximum luminance increase, can be seen from the curves.

<Description of the Reference Numerals in the Drawings>

| | |
|---|---|
| 100, 100′: LED package | 110: substrate |
| 120: lead frame | 130: LED chip |
| 140: bonding wire | 150: reflector |

210: encapsulant
220: rare-earth metal oxide particles
230: phosphor particles

1. An LED (Light-Emitting Diode) package, comprising:
any one of LED chip selected from among a blue LED chip, a green LED chip, or a red LED chip; and
an LED encapsulant having a compound represented by Chemical Formula 1 below in a polymer resin.
Mₐ(OH)_{b}(CO₃)_{c}O_{d} [Chemical Formula 1]
wherein M is Sc, Y, La, Al, Lu, Ga, Zn, V, Zr, Ca, Sr, Ba, Sn, Mn, Bi or Ac,
a is 1 or 2,
b is 0 to 2,
c is 0 to 3, and
d is 0 to 3,
wherein b, c, and d are not simultaneously zero, and b and c are either simultaneously zero or simultaneously not zero.

2. The LED package of claim 1, wherein the compound represented by Chemical Formula is Y(OH)CO₃.

3. The LED package of claim 1, wherein the compound represented by Chemical Formula 1 is Y₂O₃.

4. The LED package of claim 1, wherein the compound represented by Chemical Formula 1 is contained in an amount of 30 wt % or less relative to a total composition.

5. The LED package of claim 2, wherein the Y(OH)CO₃ is contained in an amount of 1 to 20 wt % relative to a total composition.

6. The LED package of claim 3, wherein the Y₂O₃ is contained in an amount of 20 wt % or less relative to a total composition.

7. The LED package of claim 1, wherein the compound represented by Chemical Formula 1 is spherical particles having a sphericity of 0.5 to 1.

8. The LED package of claim 7, wherein the spherical particles have a particle diameter ranging from 100 nm to 2 μm.

9. The LED package of claim 8, wherein the spherical particles are monodispersed.

10. The LED package of claim 1, wherein the compound represented by Chemical Formula 1 has a refractive index ranging from 1.6 to 2.3.

11. The LED package of claim 1, wherein the polymer resin is at least one selected from the group consisting of a silicone-based resin, a phenol-based resin, an acrylic resin, polystyrene, polyurethane, a benzoguanamine resin, and an epoxy-based resin.

12. The LED package of claim 1, further comprising phosphor particles.

13. The LED package of claim 1, wherein the blue LED chip has an emission wavelength ranging from 400 to 500 nm, the green LED chip has an emission wavelength ranging from 500 to 590 nm, and the red LED chip has an emission wavelength ranging from 591 to 780 nm.

14. The LED package of claim 1, wherein the compound represented by Chemical Formula 1 is uniformly distributed in the encapsulant.
